(19) United States
(12) Patent Application Publication
(10) Pub. No.: US 2026/0330089 A1
(43) Pub. Date: Oct. 22, 2026

(54) SYSTEMS AND METHODS FOR USING DIGITAL TWINS TO SELECT AND GENERATE OPTIMIZED DATA FOR PRESENTATION TO AN ASSOCIATED USER

(71) Applicant: BANK OF AMERICA CORPORATION, Charlotte, NC (US)

(72) Inventors: Marshall A. Johnson, Summit, NJ (US); Yutong Chen, Charlotte, NC (US); Scott R. Enscoe, Waxhaw, NC (US); Ana Maxim, Arlington, VA (US); Kathlyn Rooney, Boston, MA (US); Glenn Seagraves, Denver, NC (US)

(73) Assignee: BANK OF AMERICA CORPORATION, Charlotte, NC (US)

(21) Appl. No.: 19/180,817

(22) Filed: Apr. 16, 2025

(51) Int. Cl. G06F 30/20; H04L 67/50

(52) U.S. Cl. CPC G06F 30/20; H04L 67/535

(57) ABSTRACT

Systems, computer program products, and methods are described herein for using digital twins to select and generate optimized data for presentation to an associated user. The present disclosure is configured to identify, using an artificial intelligence (AI) model, real-world users associated with an entity, receive data associated with the real-world users, wherein the data comprises at least one of characteristics and behavioral patterns of each of the real-world users or group characteristics of a subset of the real-world users, generate, using the AI model, a digital twin for each of the real-world users, based on the data associated with the real-world users, provide incoming data associated with each of the real-world users to the digital twin corresponding to each of the real-world users, cause the digital twin to generate optimized data from the incoming data, and display the optimized data to a real-world user associated with the digital twin.

### TECHNOLOGICAL FIELD

Example embodiments of the present disclosure relate to generating a network of digital twins using artificial intelligence. Specifically, the present disclosure provides for using artificial intelligence to generate digital twins to select and generate optimized data for presentation to an associated user.

### BACKGROUND

In today's electronic environment, as more and more communications and information is being generated and communicated over the digital networks, it is incredibly difficult for users to determine relevant data from the irrelevant data in the communications and the information generated and communicated over the digital networks. As such, there exists a need for a system to select and generate optimized data for presentation to an associated user.

### BRIEF SUMMARY

The following a simplified summary of one or more embodiments of the disclosure in order to provide a basic understanding of such embodiments. This summary is not an extensive overview of all contemplated embodiments and is intended to neither identify key or critical elements of all embodiments, nor delineate the scope of any or all embodiments. Its sole purpose is to present some concepts of one or more embodiments in a simplified form as a prelude to the more detailed description that is presented later.

Embodiments of the present disclosure provide for systems, methods, and computer program products and the like are provided for using digital twins to select and generate optimized data for presentation to an associated user.

In some embodiments, the present invention identifies, using an artificial intelligence (AI) model, real-world users associated with an entity, receives data associated with the real-world users, wherein the data comprises at least one of characteristics and behavioral patterns of each of the real-world users or group characteristics of a subset of the real-world users, generates, using the AI model, a digital twin for each of the real-world users, based on the data associated with the real-world users, provides incoming data associated with each of the real-world users to the digital twin corresponding to each of the real-world users, causes the digital twin to generate optimized data from the incoming data, and displays the optimized data to a real-world user associated with the digital twin.

In some embodiments, the present invention implements a smart contract to control use of the incoming data and the optimized data generated from the incoming data by the digital twin.

In some embodiments, the present invention provides at least one parameter associated with the real-world user to the digital twin, wherein the at least one parameter is used by the digital twin to generate the optimized data.

In some embodiments, the at least one parameter comprises at least one of user preferences, user goals, and user requirements associated with the real-world user.

In some embodiments, one or more of the real-world users train digital twin counterparts of the real-world users, wherein training the digital twin counterparts comprises receiving input from the real-world users, generating, using the AI model, and transmitting output to the real-world users, analyzing, using the AI model, the input and the output, and training, using the AI model, the digital twin counterparts of the real-world users using the analysis of the input and the output

In some embodiments, training the digital twin counterparts further comprise receiving input, generating and transmitting output, analyzing the input and output, and training the digital twin continuously and repeatedly until an end of a user session with the real-world user.

In some embodiments, the present invention causes the digital twin to performs actions autonomously, at an instruction of the real-world user, wherein the actions are associated with the optimized data generated by the digital twin.

In some embodiments, receiving the data associated with the real-world users comprises at least one of collecting the data in real time from the real-world users; or collecting the data from logs of historical data associated with the real-world users.

In some embodiments, the present invention generates one or more simulations associated with the real-world user, via the digital twin.

Similarly, and as a person of skill in the art will understand, each of the features, functions, and advantages provided herein with respect to the system disclosed herein above may additionally be provided with respect to a computer-implemented method and computer program product. Such embodiments are provided for exemplary purposes below and are not intended to be limited.

The above summary is provided merely for purposes of summarizing some example embodiments to provide a basic understanding of some aspects of the present disclosure. The features, functions, and advantages that have been discussed may be achieved independently in various embodiments of the present disclosure or may be combined with yet other embodiments, further details of which can be seen with reference to the following description and drawings. Accordingly, it will be appreciated that the above-described embodiments are merely examples and should not be construed to narrow the scope or spirit of the disclosure in any way. It will be appreciated that the scope of the present disclosure encompasses many potential embodiments in addition to those here summarized, some of which will be further described below.

### BRIEF DESCRIPTION OF THE DRAWINGS

Having thus described embodiments of the disclosure in general terms, reference will now be made the accompanying drawings. The components illustrated in the figures may or may not be present in certain embodiments described herein. Some embodiments may include fewer (or more) components than those shown in the figures.

FIGS. 1A-1C illustrate technical components of an exemplary distributed computing environment for using digital twins to select and generate optimized data for presentation to an associated user, in accordance with an embodiment of the disclosure;

FIG. 2 illustrates an exemplary architecture of a machine learning (ML) subsystem, in accordance with an embodiment of the disclosure.

FIG. 3 illustrates an exemplary generative AI subsystem 300, in accordance with an embodiment of the disclosure.

FIG. 4 illustrates a process flow for generating a network of digital twins using artificial intelligence, in accordance with an embodiment of the disclosure.

FIG. 5 illustrates a process flow for training digital twin counterparts, in accordance with an embodiment of the disclosure.

FIG. 6 illustrates a process flow for generating and selecting optimized data for presentation to an associated user, in accordance with an embodiment of the disclosure.

### DETAILED DESCRIPTION

Embodiments of the present disclosure will now be described more fully hereinafter with reference to the accompanying drawings, in which some, but not all, embodiments of the disclosure are shown. Indeed, the disclosure may be embodied in many different forms and should not be construed as limited to the embodiments set forth herein; rather, these embodiments are provided so that this disclosure will satisfy applicable legal requirements. Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Furthermore, when it is said herein that something is “based on” something else, it may be based on one or more other things as well. In other words, unless expressly indicated otherwise, as used herein “based on” means “based at least in part on” or “based at least partially on.” Like numbers refer to like elements throughout.

As used herein, an “entity” may be any institution employing information technology resources and particularly technology infrastructure configured for processing large amounts of data. Typically, this data may be related to the people who work for the organization, its products or services, the customers, or any other aspect of the operations of the organization. As such, the entity may be any institution, group, association, financial institution, establishment, company, union, authority, or the like, employing information technology resources for processing large amounts of data.

As described herein, a “user” may be an individual associated with an entity. As such, in some embodiments, the user may be an individual having past relationships, current relationships, or potential future relationships with an entity. In some embodiments, the user may be an employee (e.g., an associate, a project manager, an IT specialist, a manager, an administrator, an internal operations analyst, or the like) of the entity or enterprises affiliated with the entity.

As used herein, a “user interface” may be a point of human-computer interaction and communication in a device that allows a user to input information, such as commands or data, into a device, or that allows the device to output information to the user. For example, the user interface may include a graphical user interface (GUI) or an interface to input computer-executable instructions that direct a processor to carry out specific functions. The user interface typically employs certain input and output devices such as a display, mouse, keyboard, button, touchpad, touch screen, microphone, speaker, LED, light, joystick, switch, buzzer, bell, and/or other user input/output device for communicating with one or more users.

As used herein, “authentication credentials” may be any information that may be used to identify a user. For example, a system may prompt a user to enter authentication information such as a username, a password, a personal identification number (PIN), a passcode, biometric information (e.g., iris recognition, retina scans, fingerprints, finger veins, palm veins, palm prints, digital bone anatomy/structure, and positioning (e.g., distal phalanges, intermediate phalanges, proximal phalanges, and the like)), an answer to a security question, a unique intrinsic user activity (e.g., making a predefined motion with a user device), and/or the like. This authentication information may be used to authenticate the identity of the user (e.g., determine that the authentication information is associated with the account) and determine that the user has authority to access an account or system. In some embodiments, the system may be owned or operated by an entity. In such embodiments, the entity may employ additional computer systems, such as authentication servers, to validate and certify resources input by the plurality of users within the system. The system may further use its authentication servers to certify the identity of users of the system, such that other users may verify the identity of the certified users. In some embodiments, the entity may certify the identity of the other users. Furthermore, authentication information or permission may be assigned to or required from a user, application, computing node, computing cluster, or the like to access stored data within at least a portion of the system.

It should also be understood that “operatively coupled,” as used herein, means that the components may be formed integrally with each other, or may be formed separately and coupled together. Furthermore, “operatively coupled” means that the components may be formed directly to each other, or to each other with one or more components located between the components that are operatively coupled together. Furthermore, “operatively coupled” may mean that the components are detachable from each other, or that they are permanently coupled together. Furthermore, operatively coupled components may mean that the components retain at least some freedom of movement in one or more directions or may be rotated about an axis (e.g., rotationally coupled, pivotally coupled, or the like). Furthermore, “operatively coupled” may mean that components may be electronically connected and/or in fluid communication with one another.

As used herein, an “interaction” may refer to any communication between one or more users, one or more entities or institutions, one or more devices, nodes, clusters, or systems within the distributed computing environment described herein. For example, an interaction may refer to a transfer of data between devices, an accessing of stored data by one or more nodes of a computing cluster, a transmission of a requested task, or the like.

It should be understood that the word “exemplary” is used herein to mean “serving as an example, instance, or illustration.” Any implementation described herein as “exemplary” is not necessarily to be construed as advantageous over other implementations.

As used herein, “determining” may encompass a variety of actions. For example, “determining” may include calculating, computing, processing, deriving, investigating, ascertaining, and/or the like. Furthermore, “determining” may also include receiving (e.g., receiving information), accessing (e.g., accessing data in a memory), and/or the like. Also, “determining” may include resolving, selecting, choosing, calculating, establishing, and/or the like. Determining may also include ascertaining that a parameter matches a predetermined criterion, including that a threshold has been met, passed, exceeded, and so on.

As used herein, “satisfying the threshold” or “meeting the threshold” may, depending on the context, refer to a value being greater than the threshold, more than the threshold, higher than the threshold, greater than or equal to the threshold, less than the threshold, fewer than the threshold, lower than the threshold, less than or equal to the threshold, equal to the threshold, or the like.

As used herein, a “resource” may generally refer to objects, products, devices, goods, commodities, services, and the like, and/or the ability and opportunity to access and use the same. Some example implementations herein contemplate property held by a user, including property that is stored and/or maintained by a third-party entity. In some example implementations, a resource may be associated with one or more accounts or may be property that is not associated with a specific account. Examples of resources associated with accounts may be accounts that have cash or cash equivalents, commodities, and/or accounts that are funded with or contain property, such as safety deposit boxes containing jewelry, art or other valuables, a trust account that is funded with property, or the like. For purposes of this disclosure, a resource is typically stored in a resource repository-a storage location where one or more resources are organized, stored, and retrieved electronically using a computing device.

As used herein, a “resource transfer,” “resource distribution,” or “resource allocation” may refer to any transactions, activities, or communications between one or more entities, or between the user and the one or more entities. A resource transfer may refer to any distribution of resources such as, but not limited to, a payment, processing of funds, purchase of goods or services, a return of goods or services, a payment transaction, a credit transaction, or other interactions involving a user's resource or account. Unless specifically limited by the context, a “resource transfer” a “transaction”, “transaction event” or “point of transaction event” may refer to any activity between a user, a merchant, an entity, or any combination thereof. In some embodiments, a resource transfer or transaction may refer to financial transactions involving direct or indirect movement of funds through traditional paper transaction processing systems (e.g., paper check processing) or through electronic transaction processing systems. Typical financial transactions include point of sale (POS) transactions, automated teller machine (ATM) transactions, person-to-person (P2P) transfers, internet transactions, online shopping, electronic funds transfers between accounts, transactions with a financial institution teller, personal checks, conducting purchases using loyalty/rewards points, etc. When discussing that resource transfers or transactions are evaluated, it could mean that the transaction has already occurred, is in the process of occurring or being processed, or that the transaction has yet to be processed/posted by one or more financial institutions. In some embodiments, a resource transfer or transaction may refer to non-financial activities of the user. In this regard, the transaction may be a customer account event, such as but not limited to the customer changing a password, ordering new checks, adding new accounts, opening new accounts, adding or modifying account parameters/restrictions, modifying a payee list associated with one or more accounts, setting up automatic payments, performing/modifying authentication procedures and/or credentials, and the like.

As used herein, “payment instrument” may refer to an electronic payment vehicle, such as an electronic credit or debit card. The payment instrument may not be a “card” at all and may instead be account identifying information stored electronically in a user device, such as payment credentials or tokens/aliases associated with a digital wallet, or account identifiers stored by a mobile application.

According to embodiments of the disclosure, which will be described in more detail below, systems, methods and computer program products are disclosed that provide for generating a network of digital twins using artificial intelligence. Specifically, a network of digital twins that reflects a set of real-world users can be used to select and generate optimized data for presentation to an associated user.

In today's environment, it is increasingly difficult for a real-world user to track incoming data received via a plurality of incoming data channels. With the constant influx of incoming data, data that is relevant to the real-world user may be missed when the real-world user is reviewing the incoming data. As such, there exists a need for a system to select and generate optimized data for presentation to the real-world user and also to perform one or more tasks on behalf of the real-world user.

The present disclosure, therefore, provides for using artificial intelligence to generate a network of digital twins, where the digital twins represent and can essentially behave like (i.e., perform tasks or generate responses similar to) their real-world counterparts and the network represents a set of real-world users associated with the entity. The digital twins are generated using data associated with real-world users, where such data can be collected in real time or through historical records associated with the real-world users. The digital twins can interact with each other or with real-world users and can perform tasks and generate feedback. As such, entities can use digital twins as a substitute for real-world users to gather feedback regarding their products and offerings. Additionally, entities can use digital twins to perform and thereby automate certain tasks typically performed by real-world users.

Accordingly, the present disclosure provides for identifying, using artificial intelligence (AI), real-world users associated with an entity and receiving data associated with the real-world users. The data comprises at least one of characteristics and behavioral patterns of each of the real-world users or group characteristics of a subset of the real-world users and receiving the data associated with the real-world users may comprise at least one of collecting the data in real time from the real-world users or collecting the data from logs of historical data associated with the real-world users.

The disclosure further provides for generating, using AI, digital twins, wherein each of the digital twins has a real-world user counterpart, and generating, using AI, a network, wherein the network comprises a plurality of digital twins. In some embodiments, each of the digital twins may, within the network, have the same role as the real-world user counterpart of the digital twin and may perform certain tasks. A digital twin may perform tasks autonomously or at the instruction of a real-world user or another digital twin in the network. Each of the digital twins within the network may interact with each other, wherein interaction may occur as a transmission of data between one or more digital twins. In some embodiments, the digital twins may be trained by one or more of the real-world users. Training the digital twins may comprise receiving input from the real-world users; generating, using AI, and transmitting output to the real-world users; analyzing, using AI, the input and the output; and training, using AI, the digital twin counterparts of the real-world users using the analysis of the input and the output. Training the digital twin counterpart may further comprise receiving input, generating and transmitting output, analyzing the input and output, and training the digital twin continuously and repeatedly until the end of a user session with the real-world user.

In some embodiments, the digital twins can monitor incoming data associated with the real-world user from a plurality of incoming data channels, select relevant data from the incoming data to generate optimized data based on one or more parameters to present to the real-world user, generate one or more optimized plans for the real-world user based on the one or more parameters, generate simulations of the optimized plans, and autonomously implement one or more actions associated with an optimized plan approved by the real-world user.

What is more, the present disclosure provides a technical solution to a technical problem. As described herein, the technical problem includes the difficulty of determining relevant data from incoming data. The technical solution presented herein allows for generating a network of digital twins that represent real-world users and can be used as substitutes that can provide feedback in the place of real-world users, such that the real-world users may rely on the digital twins to present relevant data from the incoming data and to perform one or more actions autonomously on behalf of the real-world users. In particular, generating digital twins that can be used to obtain feedback is an improvement over existing solutions for generated optimized data for the real-world users, (i) with fewer steps to achieve the solution, thus reducing the amount of computing resources, such as processing resources, storage resources, network resources, and/or the like, that are being used, (ii) providing a more accurate solution to problem, thus reducing the number of resources required to remedy any errors made due to a less accurate solution, (iii) removing manual input and waste from the implementation of the solution, thus improving speed and efficiency of the process and conserving computing resources, (iv) determining an optimal amount of resources that need to be used to implement the solution, thus reducing network traffic and load on existing computing resources. Furthermore, the technical solution described herein uses a rigorous, computerized process to perform specific tasks and/or activities that were not previously performed. In specific implementations, the technical solution bypasses a series of steps previously implemented, thus further conserving computing resources.

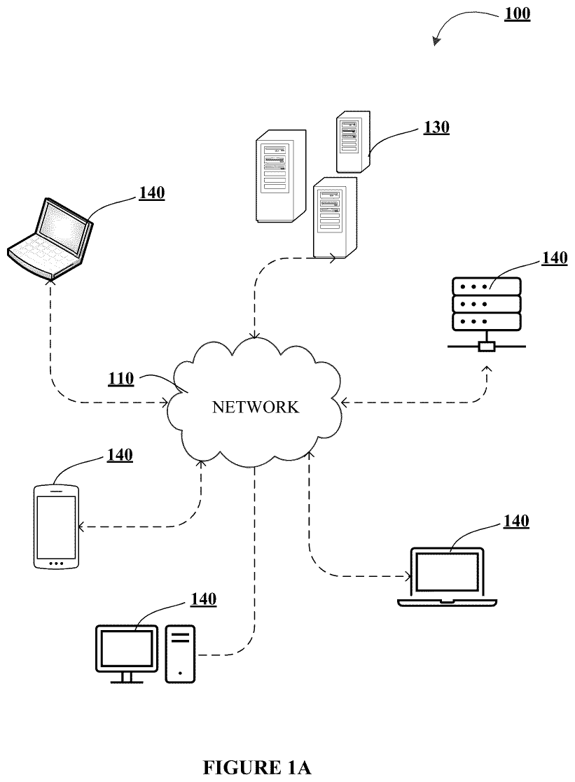

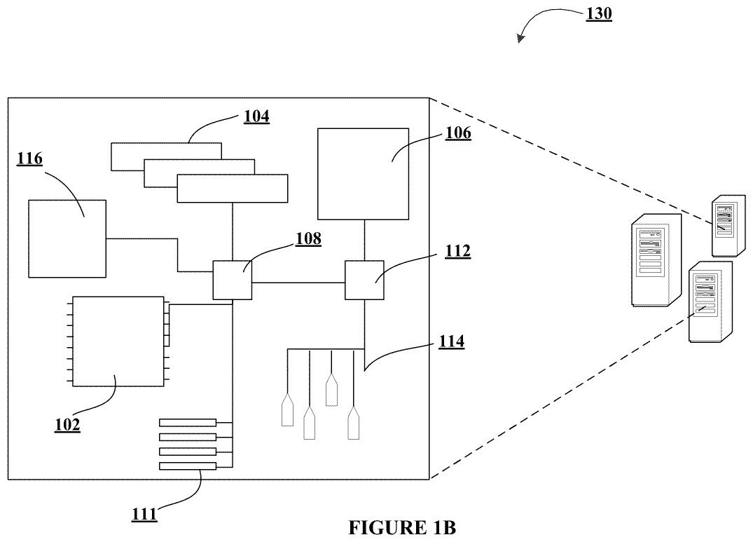

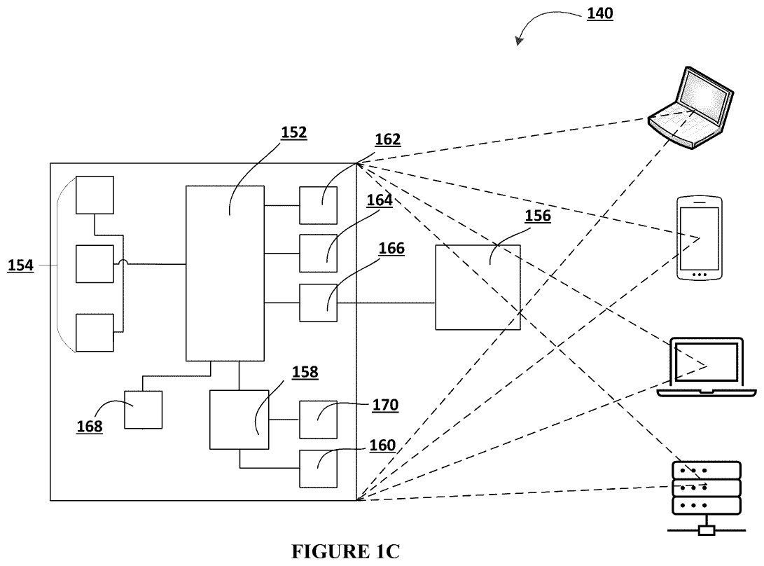

FIGS. 1A-1C illustrate technical components of an exemplary distributed computing environment for using digital twins to select and generate optimized data for presentation to an associated user 100, in accordance with an embodiment of the disclosure. As shown in FIG. 1A, the distributed computing environment 100 contemplated herein may include a system 130, an end-point device(s) 140, and a network 110 over which the system 130 and end-point device(s) 140 communicate therebetween. FIG. 1A illustrates only one example of an embodiment of the distributed computing environment 100, and it will be appreciated that in other embodiments one or more of the systems, devices, and/or servers may be combined into a single system, device, or server, or be made up of multiple systems, devices, or servers. Also, the distributed computing environment 100 may include multiple systems, same or similar to system 130, with each system providing portions of the necessary operations (e.g., as a server bank, a group of blade servers, or a multi-processor system).

In some embodiments, the system 130 and the end-point device(s) 140 may have a client-server relationship in which the end-point device(s) 140 are remote devices that request and receive service from a centralized server, i.e., the system 130. In some other embodiments, the system 130 and the end-point device(s) 140 may have a peer-to-peer relationship in which the system 130 and the end-point device(s) 140 are considered equal and all have the same abilities to use the resources available on the network 110. Instead of having a central server (e.g., system 130) which would act as the shared drive, each device that is connected to the network 110 would act as the server for the files stored on it.

The system 130 may represent various forms of servers, such as web servers, database servers, file server, or the like, various forms of digital computing devices, such as laptops, desktops, video recorders, audio/video players, radios, workstations, or the like, or any other auxiliary network devices, such as wearable devices, Internet-of-things devices, electronic kiosk devices, entertainment consoles, mainframes, or the like, or any combination of the aforementioned.

The end-point device(s) 140 may represent various forms of electronic devices, including user input devices such as personal digital assistants, cellular telephones, smartphones, laptops, desktops, and/or the like, merchant input devices such as point-of-sale (POS) devices, electronic payment kiosks, and/or the like, electronic telecommunications device (e.g., automated teller machine (ATM)), and/or edge devices such as routers, routing switches, integrated access devices (IAD), and/or the like.

The network 110 may be a distributed network that is spread over different networks. This provides a single data communication network, which may be managed jointly or separately by each network. Besides shared communication within the network, the distributed network often also supports distributed processing. The network 110 may be a form of digital communication network such as a telecommunication network, a local area network (“LAN”), a wide area network (“WAN”), a global area network (“GAN”), the Internet, or any combination of the foregoing. The network 110 may be secure and/or unsecure and may also include wireless and/or wired and/or optical interconnection technology.

It is to be understood that the structure of the distributed computing environment and its components, connections and relationships, and their functions, are meant to be exemplary only, and are not meant to limit implementations of the disclosures described and/or claimed in this document. In one example, the distributed computing environment 100 may include more, fewer, or different components. In another example, some or all of the portions of the distributed computing environment 100 may be combined into a single portion or all of the portions of the system 130 may be separated into two or more distinct portions.

FIG. 1B illustrates an exemplary component-level structure of the system 130, in accordance with an embodiment of the disclosure. As shown in FIG. 1B, the system 130 may include a processor 102, memory 104, input/output (I/O) device 116, and a storage device 106. The system 130 may also include a high-speed interface 108 connecting to the memory 104, and a low-speed interface 112 connecting to low-speed bus 114 and storage device 106. Each of the components 102, 104, 106, 108, 112 and 114 may be operatively coupled to one another using various buses and may be mounted on a common motherboard or in other manners as appropriate. As described herein, the processor 102 may include a number of subsystems to execute the portions of processes described herein. Each subsystem may be a self-contained component of a larger system (e.g., system 130) and capable of being configured to execute specialized processes as part of the larger system.

The processor 102 can process instructions, such as instructions of an application that may perform the functions disclosed herein. These instructions may be stored in the memory 104 (e.g., non-transitory storage device) or on the storage device 106, for execution within the system 130 using any subsystems described herein. It is to be understood that the system 130 may use, as appropriate, multiple processors, along with multiple memories, and/or I/O devices, to execute the processes described herein.

The memory 104 stores information within the system 130. In one implementation, the memory 104 is a volatile memory unit or units, such as volatile random access memory (RAM) having a cache area for the temporary storage of information, such as a command, a current operating state of the distributed computing environment 100, an intended operating state of the distributed computing environment 100, instructions related to various methods and/or functionalities described herein, and/or the like. In another implementation, the memory 104 is a non-volatile memory unit or units. The memory 104 may also be another form of computer-readable medium, such as a magnetic or optical disk, which may be embedded and/or may be removable. The non-volatile memory may additionally or alternatively include an EEPROM, flash memory, and/or the like for storage of information such as instructions and/or data that may be read during execution of computer instructions. The memory 104 may store, recall, receive, transmit, and/or access various files and/or information used by the system 130 during operation.

The storage device 106 is capable of providing mass storage for the system 130. In one aspect, the storage device 106 may be or contain a computer-readable medium, such as a floppy disk device, a hard disk device, an optical disk device, or a tape device, a flash memory or other similar solid state memory device, or an array of devices, including devices in a storage area network or other configurations. A computer program product may be tangibly embodied in an information carrier. The computer program product may also contain instructions that, when executed, perform one or more methods, such as those described above. The information carrier may be a non-transitory computer-or machine-readable storage medium, such as the memory 104, the storage device 106, or memory on processor 102.

The high-speed interface 108 manages bandwidth-intensive operations for the system 130, while the low-speed interface/controller 112 manages lower bandwidth-intensive operations. Such allocation of functions is exemplary only. In some embodiments, the high-speed interface 108 is coupled to memory 104, input/output (I/O) device 116 (e.g., through a graphics processor or accelerator), and to high-speed expansion ports 111, which may accept various expansion cards (not shown). In such an implementation, the low-speed interface/controller 112 is coupled to storage device 106 and low-speed bus/expansion port 114. The low-speed bus/expansion port 114, which may include various communication ports (e.g., USB, Bluetooth, Ethernet, wireless Ethernet), may be coupled to one or more input/output devices, such as a keyboard, a pointing device, a scanner, or a networking device such as a switch or router, e.g., through a network adapter.

The system 130 may be implemented in a number of different forms. For example, the system 130 may be implemented as a standard server, or multiple times in a group of such servers. Additionally, the system 130 may also be implemented as part of a rack server system or a personal computer such as a laptop computer. Alternatively, components from system 130 may be combined with one or more other same or similar systems and an entire system 130 may be made up of multiple computing devices communicating with each other.

FIG. 1C illustrates an exemplary component-level structure of the end-point device(s) 140, in accordance with an embodiment of the disclosure. As shown in FIG. 1C, the end-point device(s) 140 includes a processor 152, memory 154, an input/output device such as a display 156, a communication interface 158, and a transceiver 160, among other components. The end-point device(s) 140 may also be provided with a storage device, such as a microdrive or other device, to provide additional storage. Each of the components 152, 154, 158, and 160, are interconnected using various buses, and several of the components may be mounted on a common motherboard or in other manners as appropriate.

The processor 152 is configured to execute instructions within the end-point device(s) 140, including instructions stored in the memory 154, which in one embodiment includes the instructions of an application that may perform the functions disclosed herein, including certain logic, data processing, and data storing functions. The processor 152 may be implemented as a chipset of chips that include separate and multiple analog and digital processors. The processor 152 may be configured to provide, for example, for coordination of the other components of the end-point device(s) 140, such as control of user interfaces, applications run by end-point device(s) 140, and wireless communication by end-point device(s) 140.

The processor 152 may be configured to communicate with the user through control interface 164 and display interface 166 coupled to a display 156. The display 156 may be, for example, a TFT LCD (Thin-Film-Transistor Liquid Crystal Display) or an OLED (Organic Light Emitting Diode) display, or other appropriate display technology. The display interface 166 may comprise appropriate circuitry and may be configured for driving the display 156 to present graphical and other information to a user. The control interface 164 may receive commands from a user and convert them for submission to the processor 152. In addition, an external interface 168 may be provided in communication with processor 152, so as to enable near area communication of end-point device(s) 140 with other devices. External interface 168 may provide, for example, for wired communication in some implementations, or for wireless communication in other implementations, and multiple interfaces may also be used.

The memory 154 stores information within the end-point device(s) 140. The memory 154 may be implemented as one or more of a computer-readable medium or media, a volatile memory unit or units, or a non-volatile memory unit or units. Expansion memory may also be provided and connected to end-point device(s) 140 through an expansion interface (not shown), which may include, for example, a SIMM (Single In Line Memory Module) card interface. Such expansion memory may provide extra storage space for end-point device(s) 140 or may also store applications or other information therein. In some embodiments, expansion memory may include instructions to carry out or supplement the processes described above and may include secure information also. For example, expansion memory may be provided as a security module for end-point device(s) 140 and may be programmed with instructions that permit secure use of end-point device(s) 140. In addition, secure applications may be provided via the SIMM cards, along with additional information, such as placing identifying information on the SIMM card in a non-hackable manner.

The memory 154 may include, for example, flash memory and/or NVRAM memory. In one aspect, a computer program product is tangibly embodied in an information carrier. The computer program product contains instructions that, when executed, perform one or more methods, such as those described herein. The information carrier may be a computer-or machine-readable medium, such as the memory 154, expansion memory, memory on processor 152, or a propagated signal that may be received, for example, over transceiver 160 or external interface 168.

In some embodiments, the user may use the end-point device(s) 140 to transmit and/or receive information or commands to and from the system 130 via the network 110. Any communication between the system 130 and the end-point device(s) 140 may be subject to an authentication protocol allowing the system 130 to maintain security by permitting only authenticated users (or processes) to access the protected resources of the system 130, which may include servers, databases, applications, and/or any of the components described herein. To this end, the system 130 may trigger an authentication subsystem that may require the user (or process) to provide authentication credentials to determine whether the user (or process) is eligible to access the protected resources. Once the authentication credentials are validated and the user (or process) is authenticated, the authentication subsystem may provide the user (or process) with permissioned access to the protected resources. Similarly, the end-point device(s) 140 may provide the system 130 (or other client devices) permissioned access to the protected resources of the end-point device(s) 140, which may include a GPS device, an image capturing component (e.g., camera), a microphone, and/or a speaker.

The end-point device(s) 140 may communicate with the system 130 through the communication interface 158, which may include digital signal processing circuitry where necessary. The communication interface 158 may provide for communications under various modes or protocols, such as the Internet Protocol (IP) suite (commonly known as TCP/IP). Protocols in the IP suite define end-to-end data handling methods for everything from packetizing, addressing and routing, to receiving. Broken down into layers, the IP suite includes the link layer, containing communication methods for data that remains within a single network segment (link); the Internet layer, providing internetworking between independent networks; the transport layer, handling host-to-host communication; and the application layer, providing process-to-process data exchange for applications. Each layer contains a stack of protocols used for communications. In addition, the communication interface 158 may provide for communications under various telecommunications standards (2G, 3G, 4G, 5G, and/or the like) using their respective layered protocol stacks. These communications may occur through a transceiver 160, such as radio-frequency transceiver. In addition, short-range communication may occur, such as using a Bluetooth, Wi-Fi, or other such transceiver (not shown). In addition, a GPS (Global Positioning System) receiver module 170 may provide additional navigation-and location-related wireless data to end-point device(s) 140, which may be used as appropriate by applications running thereon, and in some embodiments, one or more applications operating on the system 130.

The end-point device(s) 140 may also communicate audibly using an audio codec 162, which may receive spoken information from a user and convert the spoken information to usable digital information. The audio codec 162 may likewise generate audible sound for a user, such as through a speaker (e.g., in a handset of end-point device(s) 140). Such sound may include sound from voice telephone calls, may include recorded sound (e.g., voice messages, music files, etc.) and may also include sound generated by one or more applications operating on the end-point device(s) 140, and in some embodiments, one or more applications operating on the system 130.

Various implementations of the distributed computing environment 100, including the system 130 and end-point device(s) 140, and techniques described herein may be realized in digital electronic circuitry, integrated circuitry, specially designed ASICs (application specific integrated circuits), computer hardware, firmware, software, and/or combinations thereof.

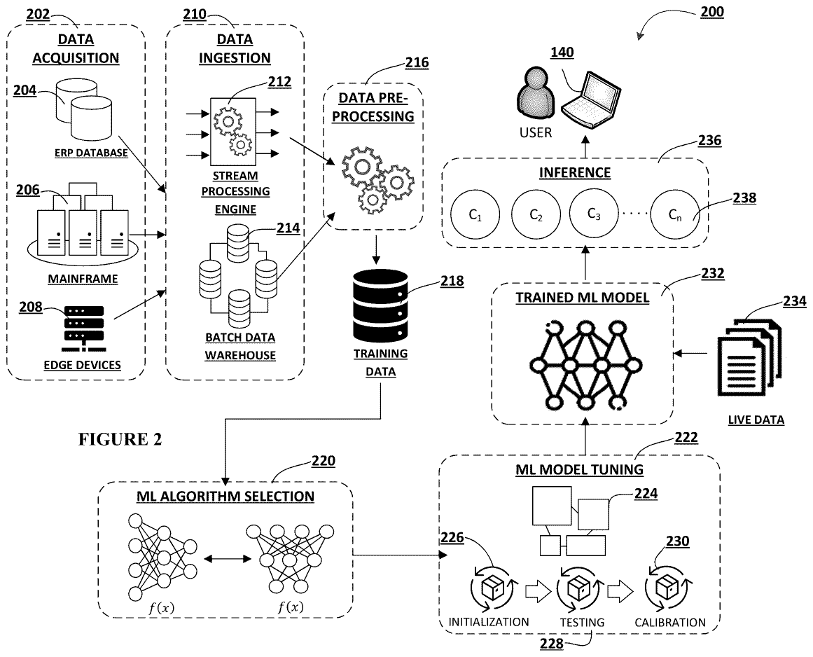

FIG. 2 illustrates an exemplary architecture of a machine learning (ML) subsystem 200, in accordance with an embodiment of the disclosure. The machine learning subsystem 200 may include a data acquisition engine 202, data ingestion engine 210, data pre-processing engine 216, ML model tuning engine 222, and inference engine 236.

The data acquisition engine 202 may identify various internal and/or external data sources to generate, test, and/or integrate new features for training the machine learning model 224. These internal and/or external data sources 204, 206, and 208 may be initial locations where the data originates or where physical information is first digitized. The data acquisition engine 202 may identify the location of the data and may describe connection characteristics for access and retrieval of data. In some embodiments, data is transported from each data source 204, 206, or 208 using any applicable network protocols, such as the File Transfer Protocol (FTP), Hyper-Text Transfer Protocol (HTTP), or any of the myriad of Application Programming Interfaces (APIs) provided by websites, networked applications, and other services. In some embodiments, the these data sources 204, 206, and 208 may include Enterprise Resource Planning (ERP) databases that host data related to day-to-day business activities such as accounting, procurement, project management, exposure management, supply chain operations, and/or the like, mainframes that are often the entity's central data processing center, edge devices that may be any piece of hardware, such as sensors, actuators, gadgets, appliances, or machines, that may be programmed for certain applications and may transmit data over the internet or other networks, and/or the like. The data acquired by the data acquisition engine 202 from these data sources 204, 206, and 208 may then be transported to the data ingestion engine 210 for further processing.

Depending on the nature of the data imported from the data acquisition engine 202, the data ingestion engine 210 may move the data to a destination for storage or further analysis. Typically, the data imported from the data acquisition engine 202 may be in varying formats as they come from different sources, including RDBMS, other types of databases, S3 buckets, CSVs, or from streams. Since the data comes from different locations, the data may need to be cleansed and transformed so that it may be analyzed together with data from other sources. At the data ingestion engine 210, the data may be ingested in real-time, using the stream processing engine 212, in batches using the batch data warehouse 214, or in a combination of both. The stream processing engine 212 may be used to process continuous data streams (e.g., data from edge devices) by computing on data directly as it is received, and filtering the incoming data to retain specific portions that are deemed useful by aggregating, analyzing, transforming, and/or ingesting the data. On the other hand, the batch data warehouse 214 may collect and transfer data in batches according to scheduled intervals, triggered events, and/or any other logical ordering.

In machine learning, the quality of data and the useful information that may be derived therefrom, directly affects the ability of the machine learning model 224 to learn. The data pre-processing engine 216 may implement advanced integration and processing steps needed to prepare the data for machine learning execution. This may include modules to perform any upfront data transformations to consolidate the data into alternate forms by changing the value, structure, and/or format of the data by using generalization, normalization, attribute selection, and aggregation, to data clean by filling missing values, smoothing noisy data, resolving inconsistent data, removing outliers, and/or any other encoding steps as needed.

In addition to improving the quality of the data, the data pre-processing engine 216 may implement feature extraction and/or selection techniques to generate training data 218. Feature extraction and/or selection is a process of transforming and/or reducing the data into new features that may better represent underlying patterns in the data. Additionally, or alternatively, feature extraction and/or selection may be a process of dimensionality reduction by which an initial set of data is reduced to more manageable groups for processing. A characteristic of these large data sets is a large number of variables that require a lot of computing resources to process. Feature extraction and/or selection may be used to select and/or combine variables into features, effectively reducing the amount of data that must be processed, while still accurately and completely describing the original data set. Depending on the type of machine learning algorithm being used, this training data 218 may require further enrichment. For example, in supervised learning, the training data may be enriched using one or more meaningful and informative labels to provide context such that a machine learning model may learn from the provided context. For example, labels may indicate whether a photo contains a bird or a car, which words were uttered in an audio recording, or if an x-ray contains a tumor. Data labeling is required for a variety of use cases including computer vision, natural language processing, and speech recognition. In contrast, unsupervised learning may use unlabeled data to find patterns in the data, such as inferences or clustering of data points.

The ML model tuning engine 222 may be used to train a machine learning model 224 using the training data 218 to make predictions or decisions without explicitly being programmed to do so. The machine learning model 224 represents what was learned by the selected machine learning algorithm 220 and represents the rules, numbers, and any other algorithm-specific data structures required for classification. Selecting the right machine learning algorithm may depend on a number of different factors, such as the problem statement and the kind of output needed, the type and the size of the data, the available computational time, the number of features and observations in the data, and/or the like. Machine learning algorithms may refer to programs (e.g., math and logic) that may be configured to self-adjust and perform better as they are exposed to more data. To this extent, machine learning algorithms are capable of adjusting their own parameters, given feedback on previous performance in making prediction about a dataset.

The machine learning algorithms contemplated, described, and/or used herein include supervised learning (e.g., using logistic regression, using back propagation neural networks, using random forests, decision trees, or the like), unsupervised learning (e.g., using an Apriori algorithm, using K-means clustering), semi-supervised learning, reinforcement learning (e.g., using a Q-learning algorithm, using temporal difference learning), and/or any other suitable machine learning model type. Each of these types of machine learning algorithms can implement any of one or more of a regression algorithm (e.g., ordinary least squares, logistic regression, stepwise regression, multivariate adaptive regression splines, locally estimated scatterplot smoothing, or the like), an instance-based method (e.g., k-nearest neighbor, learning vector quantization, self-organizing map, or the like), a regularization method (e.g., ridge regression, least absolute shrinkage and selection operator, elastic net, or the like), a decision tree learning method (e.g., classification and regression tree, iterative dichotomiser 3, C4.5, chi-squared automatic interaction detection, decision stump, random forest, multivariate adaptive regression splines, gradient boosting machines, or the like), a Bayesian method (e.g., naïve Bayes, averaged one-dependence estimators, Bayesian belief network, or the like), a kernel method (e.g., a support vector machine, a radial basis function, or the like), a clustering method (e.g., k-means clustering, expectation maximization, or the like), an associated rule learning algorithm (e.g., an Apriori algorithm, an Eclat algorithm, or the like), an artificial neural network model (e.g., a Perceptron method, a back-propagation method, a Hopfield network method, a self-organizing map method, a learning vector quantization method, or the like), a deep learning algorithm (e.g., a restricted Boltzmann machine, a deep belief network method, a convolution network method, a stacked auto-encoder method, or the like), a dimensionality reduction method (e.g., principal component analysis, partial least squares regression, Sammon mapping, multidimensional scaling, projection pursuit, or the like), an ensemble method (e.g., boosting, bootstrapped aggregation, AdaBoost, stacked generalization, gradient boosting machine method, random forest method, or the like), and/or the like.

To tune the machine learning model, the ML model tuning engine 222 may repeatedly execute cycles of experimentation including initialization 226, testing 228, and/or calibration 230 to optimize the performance of the machine learning algorithm 220 and refine the results in preparation for deployment of those results for consumption or decision making. To this end, the ML model tuning engine 222 may dynamically vary hyperparameters each iteration (e.g., number of trees in a tree-based algorithm or the value of alpha in a linear algorithm), run the algorithm on the data again, then compare its performance on a validation set to determine which set of hyperparameters results in the most accurate model. The accuracy of the model is the measurement used to determine which set of hyperparameters is best at identifying relationships and patterns between variables in a dataset based on the input, or training data 218. A fully trained machine learning model 232 is one whose hyperparameters are tuned and whose model accuracy is maximized.

The trained machine learning model 232, similar to any other software application output, may be persisted to storage, file, memory, or application, or looped back into the processing component to be reprocessed. More often, the trained machine learning model 232 is deployed into an existing production environment to make practical business decisions based on live data 234. To this end, the machine learning subsystem 200 uses the inference engine 236 to make such decisions. The type of decision-making may depend upon the type of machine learning algorithm used. For example, machine learning models trained using supervised learning algorithms may be used to structure computations in terms of categorized outputs (e.g., C₁, C₂, . . . , Cₙ 238) or observations based on defined classifications, represent possible solutions to a decision based on certain conditions, model complex relationships between inputs and outputs to find patterns in data or capture a statistical structure among variables with unknown relationships, and/or the like. On the other hand, machine learning models trained using unsupervised learning algorithms may be used to group (e.g., C₁, C₂, . . . , Cₙ 238) live data 234 based on how similar they are to one another to solve exploratory challenges where little may be known about the data, provide a description or label (e.g., C₁, C₂, . . . , Cₙ 238) to live data 234, such as in classification, and/or the like. These categorized outputs, groups (clusters), or labels may then be presented to the user input system 140. In still other cases, machine learning models that perform regression techniques may use live data 234 to predict or forecast continuous outcomes.

It will be understood that the embodiment of the machine learning subsystem 200 illustrated in FIG. 2 is exemplary and that other embodiments may vary. As another example, in some embodiments, the machine learning subsystem 200 may include more, fewer, or different components.

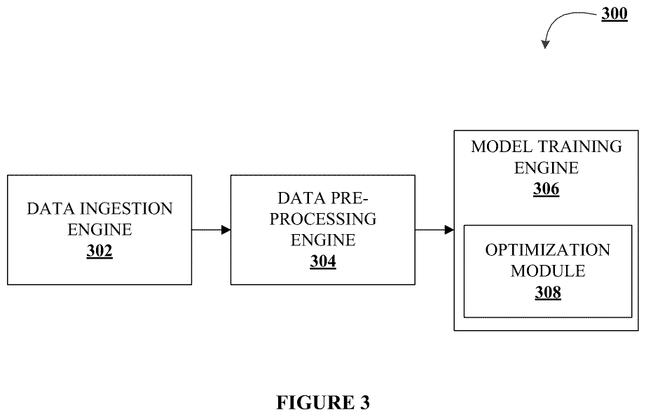

FIG. 3 illustrates an exemplary generative AI subsystem 300, in accordance with an embodiment of the disclosure. The generative AI subsystem 300 may include a data ingestion engine 302, a data pre-processing engine 304, and a model training engine 306. It should be understood that the generative AI subsystem 300 is merely an example, and other embodiments may include more, fewer, or different components depending on the specific requirements and implementations of the system. For instance, additional engines for data validation, feature selection, or distributed computing may be integrated into the subsystem, or certain components described herein may be consolidated or omitted based on system performance objectives. Therefore, the generative AI subsystem 300 should not be considered limiting and may be adapted to various configurations within the scope of the disclosure.

The data ingestion engine 302 may identify various internal and/or external data sources to generate, test, and/or integrate new features for training the generative AI model. These internal and/or external data sources (e.g., text corpora, web-based text data, document repositories, or decentralized text storage system) may be initial locations where the data originates or where physical information is first digitized. In addition to conventional data sources, the data ingestion engine 302 may support decentralized storage systems, such as blockchain-based data sources, and privacy-preserving methods such as differential privacy. The data ingestion engine 302 may identify the location of the data and describe connection characteristics for access and retrieval of data. In some embodiments, data is transported from each data source using any applicable network protocols, such as the File Transfer Protocol (FTP), Hyper-Text Transfer Protocol (HTTP), or any of the myriad Application Programming Interfaces (APIs) provided by websites, networked applications, and other services. In some embodiments, the data sources may include Enterprise Resource Planning (ERP) databases that host data related to day-to-day business activities such as accounting, procurement, project management, exposure management, supply chain operations, and/or the like, mainframes that are often the entity's central data processing center, edge devices that may be any piece of hardware, such as sensors, actuators, gadgets, appliances, or machines, that are programmed for certain applications and may transmit data over the internet or other networks, and/or the like.

Depending on the nature of the data, the data ingestion engine 302 may move the data to a destination for storage or further analysis. Typically, the data may be in varying formats as the data comes from different sources, including RDBMS, other types of databases, S3 buckets, CSVs, or from streams. For a large language model (“LLM”), text data may originate from sources such as web scrapes, social media, large public text datasets, or the like. Since the data may come from different places, the data needs to be cleansed and transformed so that the data may be analyzed together with data from other sources. The data may be ingested in real-time, using stream processing, in batches using a batch data warehouse, or in a combination of both. Stream processing may be used to process continuous data streams (e.g., data from edge devices) by computing on data directly as it is received, and filtering the incoming data to retain specific portions that are deemed useful by aggregating, analyzing, transforming, and/or ingesting the data. On the other hand, the batch data warehouse may collect and transfer data in batches according to scheduled intervals, triggered events, and/or any other logical ordering.

The generative AI subsystem 300 may utilize one or more machine learning techniques to generate new content. In machine learning, the quality of data and the useful information that may be derived therefrom directly affects the ability of the machine learning model to learn. The data pre-processing engine 304 may implement advanced integration and processing steps needed to prepare the data for machine learning execution, including tokenization, text normalization, and/or removal of irrelevant elements like HTML tags in web-based data, especially for LLM training. This may include modules to perform any upfront data transformation to consolidate the data into alternate forms by changing the value, structure, and/or format of the data by using generalization, normalization, attribute selection, aggregation, and text-specific transformations such as stemming and lemmatization to data clean by filling missing values, smoothing the noisy data, resolving the inconsistency, removing outliers, and/or any other encoding steps as needed. In some embodiments, the data pre-processing engine 304 may perform real-time pre-processing at the edge via edge computing devices, allowing for the transformation and reduction of data prior to transmission to centralized locations, thereby reducing latency and conserving network bandwidth.

In addition to improving the quality of the data, the data pre-processing engine 304 may transform categorical data into numerical formats that may be suitable for machine learning algorithms. In this regard, the data pre-processing engine 304 may use techniques such as one-hot encoding or label encoding depending on the nature of the categorical variables and the intended use of the data.

In some embodiments, the data pre-processing engine 304 may also include dimensionality reduction techniques, where the number of input features is reduced while retaining the most relevant information. In this regard, the data pre-processing engine 304 may include methods such as Principal Component Analysis (PCA) or apply feature selection algorithms to remove redundant or irrelevant features, thereby reducing the computational complexity of the model training phase. Feature selection may be particularly beneficial in datasets with a high number of features, ensuring that the generative AI models do not overfit to noise or irrelevant details. The pre-processed data output from the data pre-processing engine 304 may then be fed into the model training engine 306.

The model training engine 306 may be responsible for training the generative AI models using the pre-processed data from the data pre-processing engine 304. The model training engine 306 may implement various machine learning algorithms, including but not limited to Generative Adversarial Networks (GANs), Variational Autoencoders (VAEs), transformers, diffusion models, and/or other specialized architectures depending on the specific requirements of the system. These models may be used in a broad range of applications, such as LLMs for text generation, image generation models, video synthesis models, audio generation models, and/or the like. The model training engine 306 may optimize these models by continuously adjusting their internal parameters based on the patterns and relationships identified within the data.

In some embodiments, the model training engine 306 may include a training data handler, which manages the partitioning of the pre-processed data into training, validation, and testing datasets. The training data may be used to update the model's parameters, while the validation and testing datasets may be reserved to evaluate the model's performance during and after training. The model training engine 306 may support various data-handling strategies, such as cross-validation or random shuffling, to ensure that the model generalizes well and is not overfitting to the training data.

In embodiments involving large language models, the model training engine 306 may utilize transformer-based architectures, such as the Transformer, BERT, GPT, or the like. Transformer models rely on mechanisms like self-attention to capture dependencies between words in a sequence, regardless of their distance from one another. The self-attention mechanism allows the model to weigh the importance of different words in a sentence and establish complex relationships important for understanding context. During training, the model may process vast amounts of text data and learn to predict the next word or token in a sequence based on the input context. This training process allows LLMs to generate coherent text, complete sentences, translate languages, or answer questions based on learned patterns from the data.

The transformer-based LLMs may be trained using autoregressive (e.g., GPT) or masked-language modeling techniques (e.g., BERT). In autoregressive models, the training process may include predicting the next word in a sequence by progressively revealing more context to the model. The model iteratively improves its predictions based on its performance during prior iterations. Masked-language modeling involves masking certain words in a sentence and training the model to correctly predict the masked words based on surrounding context. Both approaches enable LLMs to capture intricate patterns in human language, improving their ability to handle tasks such as summarization, translation, and text generation. Loss functions like cross-entropy loss may be used to optimize the model's performance by comparing predicted tokens with the actual tokens in the dataset to guide the model to minimize prediction errors during training, as described in further detail herein.

In embodiments involving image generation models, the model training engine 306 may utilize transformer-based architectures, such as Vision Transformers (ViTs) or generative adversarial networks (GANs). Vision Transformers rely on self-attention mechanisms to process images as sequences of patches rather than whole images, allowing the model to capture spatial dependencies and patterns across the image. During training, the model may be exposed to large datasets containing diverse image types to learn features like textures, edges, and shapes. The model may then generate or reconstruct images by interpreting these patterns and applying learned spatial relationships. GAN-based models may also be used, where a generator network creates images, and a determinator network evaluates their realism, enabling the model to improve through adversarial training.

Image generation models may employ various training techniques, such as pixel-wise reconstruction or adversarial training, depending on the architecture. Pixel-wise reconstruction methods involve learning to reconstruct an image from its corrupted or downscaled version, optimizing the model to minimize the difference between the predicted and actual pixels (e.g., using mean squared error as the loss function). Adversarial training, often used with GANs, involves iteratively improving the generator network to produce images that are increasingly indistinguishable from real images, based on feedback from the determinator network. These approaches allow the model to capture complex visual features, enabling applications such as image synthesis, enhancement, and style transfer.

For video generation models, the model training engine 306 may employ transformer-based architectures like Video Transformers or GAN-based models specifically designed for handling temporal sequences. Video Transformers use self-attention mechanisms to model dependencies not only between pixels within a single frame but also across frames, allowing them to understand temporal relationships and motion patterns in videos. The model may be trained on large video datasets, enabling it to learn and reproduce dynamic changes and interactions between objects over time. GAN-based video models may incorporate spatiotemporal networks to evaluate the realism of generated video sequences, optimizing the model to produce continuous and coherent frames.

Video generation models may utilize spatial-temporal modeling techniques or adversarial training for generating realistic motion and video sequences. Spatial-temporal modeling involves learning the spatial features within each frame while simultaneously capturing the temporal dependencies between frames, optimizing the model's ability to predict future frames or complete missing sequences. Loss functions like mean squared error or perceptual loss may be applied to reduce discrepancies between predicted and actual frames. Adversarial training, on the other hand, may involve a generator creating video sequences and a determinator evaluating their realism, encouraging the generator to improve by minimizing the discrepancy identified by the determinator. These techniques may enable video generation models to create coherent and realistic sequences, useful in applications such as video synthesis and animation.

In audio generation models, the model training engine 306 may utilize architectures such as Audio Transformers or recurrent neural networks (RNNs) like WaveNet, designed to handle sequential and waveform data. Audio Transformers leverage attention mechanisms to capture relationships between segments of audio, allowing them to model temporal dependencies and predict the next audio sample based on previous context. During training, the model may process large audio datasets containing diverse sound patterns to learn representations of different audio features, such as frequency, amplitude, and harmonics. This training enables the model to generate coherent audio sequences, including speech, music, or ambient sounds, by synthesizing these learned patterns.

Audio generation models may be trained using sequence modeling techniques or autoregressive methods, depending on the architecture. Sequence modeling techniques involve processing and predicting sequences of audio samples, optimizing the model to capture and reproduce temporal dependencies in sound. Autoregressive methods, such as those employed in WaveNet, focus on predicting each audio sample based on prior samples, progressively refining the generated audio sequence over multiple iterations. Loss functions like mean absolute error or cross-entropy loss may be used to minimize the error between predicted and actual audio samples, guiding the model to improve its accuracy. These approaches allow audio generation models to create continuous and realistic audio outputs, applicable in areas such as speech synthesis, music generation, and sound effect creation.

The reconstruction loss ensures that the difference between the original input and the reconstructed output is minimized, guiding the decoder to generate outputs that closely resemble the input data. The second component, KL divergence loss, regularizes the latent space by ensuring that the distribution of latent variables conforms to a predefined probabilistic distribution, often a Gaussian distribution. This constraint encourages the model to learn a well-organized and smooth latent space, allowing for meaningful sampling from this space during inference. By combining these loss functions, the VAE can learn a latent space that not only captures the underlying patterns in the data but also allows for the generation of novel outputs by sampling new points from this space. During the inference phase, the trained model can sample random points from the latent space to generate new, previously unseen data instances.

In training generative AI models, the model training engine 306, which includes an optimization module 308, may implement various optimization techniques to improve model performance and efficiency. The optimization module 308 is responsible for adjusting the model's internal parameters continuously, using feedback from relevant loss functions tailored to the application (e.g., text, image, audio, or video generation). Techniques such as gradient clipping, learning rate scheduling, and mixed-precision training are applied by the optimization module 308 to stabilize and fine-tune the training process. Gradient clipping may be used to stabilize the training process, especially in transformer-based models, by capping the magnitude of gradients to prevent them from becoming excessively large. Learning rate scheduling may involve gradually increasing the learning rate during initial training phases (warm-up) and then decaying it as training progresses to fine-tune the model's parameters more effectively. Mixed-precision training, which leverages lower-precision (e.g., float16) arithmetic while retaining higher precision (e.g., float32) for specific calculations, may be used to accelerate training and reduce memory consumption, enabling the model to scale efficiently even when trained on large datasets.

In some embodiments, the model training engine 306 may implement early stopping mechanisms to prevent overfitting. Early stopping monitors the generative AI model's performance on the validation dataset, halting the training process if the performance does not improve after a specified number of iterations. This ensures that the generative AI model does not continue training on noise or irrelevant patterns, which could degrade its performance on unseen data. The model training engine 306 may also support distributed training across multiple computing nodes, allowing the system to scale its computational resources as needed. Distributed training may involve splitting the generative AI model and data across multiple machines or GPUs, where each node processes a portion of the data and updates the model in parallel. This is particularly useful for large datasets or models that require significant computational power, such as deep generative models. The model training engine 306 may synchronize the updates across the nodes using techniques like synchronous or asynchronous gradient descent.

Once the generative AI model is trained, the model training engine 306 may save the final trained generative AI model in a persistent storage location for future use. In specific embodiments, metadata such as the number of epochs, the final loss values, and values of learned parameters may be logged for model versioning and/or retraining at a later stage. In some embodiments, the model training engine 306 may also implement transfer learning, where a pre-trained model is fine-tuned on a smaller, domain-specific dataset. This may reduce the amount of time and data required to train a new model, especially in cases where the available data is limited or highly specialized. The model training engine 306 may adjust the parameters of the pre-trained model to better align with the new dataset, while preserving the learned features from the original training.

In embodiments involving LLMs, new output is generated by sampling from the model's probability distribution of tokens, conditioned on the context provided as input. Transformer-based architectures, such as GPT, use an auto-regressive approach where the model predicts the next token in a sequence one step at a time, using previously generated tokens as input for subsequent predictions. The process starts with a prompt or an initial sequence of words, and the model iteratively generates new tokens, forming coherent sentences or paragraphs based on the learned context and language patterns. For masked-language modeling (e.g., BERT), new output may be generated by filling in masked parts of the input sequence, allowing the model to complete sentences or generate variations of the provided text. The generated output can be controlled by adjusting parameters, which influences the randomness of the token sampling, enabling the generation of diverse or deterministic responses.

In image generation models, such as those using ViTs or GANs, new output is generated by sampling from the learned distribution in the model's latent space. For GANs, the generator network creates an image by transforming random noise vectors into structured image outputs through a series of layers that learn visual features like shapes, textures, and colors. The generated image is then refined through adversarial feedback from the determinator network, which assesses the realism of the generated output. For transformer-based image models, the process may involve reconstructing images by assembling patches based on the learned dependencies between them. Input conditions, such as prompts describing desired features or specific noise vectors, guide the generation process, allowing for the creation of customized images or variations of existing visual styles. These models may also generate images based on style transfer techniques or predefined templates, synthesizing images that align with the characteristics present in the training data.

Video generation models utilize spatiotemporal dependencies to synthesize new video sequences based on the patterns learned during training. In transformer-based architectures, the model may generate video frames sequentially, predicting the next frame based on the input frames and the temporal context established by prior frames. GAN-based models, specifically designed for video synthesis, may sample noise vectors or use a sequence of frames as input, transforming these into continuous and temporally coherent video outputs through the generator network. The determinator evaluates the temporal consistency and realism of the output, ensuring the generated video mimics the motion dynamics and object interactions present in real-world video data. Such models may also use attention mechanisms to focus on critical elements within each frame and their evolution across time, facilitating realistic scene transitions and motion patterns. The generation process may include user-defined input such as initial frames, motion descriptions, or specific video attributes, providing control over the output.

Audio generation models, including Audio Transformers or autoregressive architectures like WaveNet, generate new audio sequences by predicting audio samples based on learned dependencies in sequential sound data. For autoregressive models, the generation process involves producing each audio sample one at a time, conditioned on previously generated samples, allowing the model to build complex audio patterns such as speech, music, or ambient sounds. The model starts with an initial segment or a random seed and uses its learned parameters to predict and synthesize subsequent samples, constructing a continuous audio waveform. Audio Transformers, on the other hand, may use attention mechanisms to identify important temporal segments within the input audio and synthesize new output based on these learned patterns. The user can control the type of audio generated by providing parameters such as pitch, tempo, or initial sound clips, enabling the model to generate outputs tailored to specific use cases like speech synthesis, music composition, or environmental sound generation.

In some embodiments, generative AI models may also integrate multiple modalities, enabling cross-modal generation where output in one modality influences or conditions the generation in another. For example, a video generation model may use text descriptions as input, synthesizing video content that aligns with the specified narrative or visual scene described. Similarly, image generation models may generate visual representations based on audio inputs, such as generating animations synchronized to musical rhythms or speech patterns. These cross-modal systems typically involve conditional GANs or multi-modal transformers, where the model processes input from one domain (e.g., text or audio) and learns to generate output in another domain (e.g., video or image) by aligning the patterns and dependencies between the different modalities. These models may allow users to generate complex, multimodal content based on combinations of inputs, such as using textual prompts to control the visual and auditory elements of a video.

It will be understood that the embodiment of the generative AI subsystem 300 illustrated in FIG. 3 is exemplary and that other embodiments may vary. The generative AI subsystem 300, as well as its constituent elements, may vary, and modifications or alternative configurations may be implemented without departing from the broader scope of the disclosure. For instance, different machine learning algorithms, data sources, optimization techniques, or training methodologies may be employed depending on system requirements, application domain, and available computational resources. Furthermore, features and functionalities described in one embodiment may be combined with those of another embodiment as needed, and vice versa.

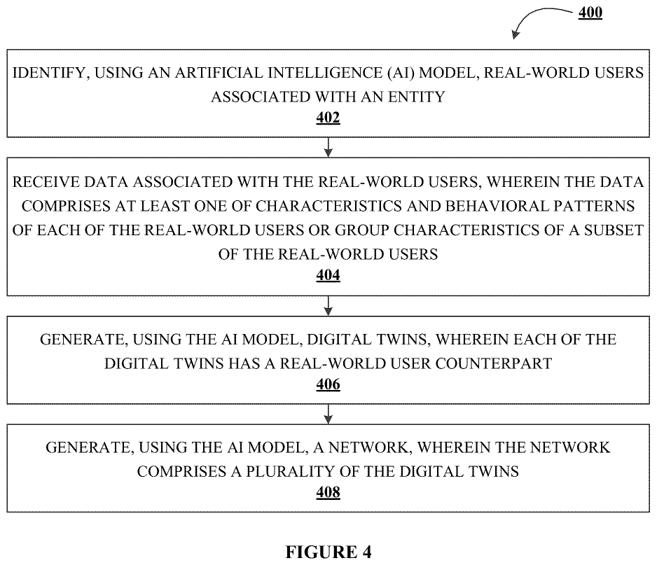

FIG. 4 illustrates a process flow 400 for generating a network of digital twins using artificial intelligence, in accordance with an embodiment of the disclosure. In some embodiments, a system (e.g., similar to one or more of the systems described herein with respect to FIGS. 1A-1C) may perform one or more of the steps of process flow 400. For example, a system (e.g., the system 130 described herein with respect to FIGS. 1A-1C) may perform the steps of process flow 400. Additionally, and in some embodiments, an ML model (like the ML model shown and described above with respect to FIG. 2) and/or a generative AI model (like that shown and described above with respect to FIG. 3) may perform one or more of the steps of process flow 400.

As shown in block 402, the process flow 400 may include the step of identifying real-world users associated with an entity. In some embodiments an artificial intelligence (AI) model may be used to identify the real-world users. In some embodiments, the AI model may comprise an ML model, as described in FIG. 2 herein. For example, and in some embodiments, an AI model may be used to analyze data and ascertain from that data individuals or types or groups of individuals that are associated with the entity. For example, an AI model may analyze multiple surveys regarding customers of various entities and identify from the surveys, customers, or at least characteristics of the customers, of the entity in question.

Real-world users associated with an entity may comprise the entity's customers, employees or stakeholders. In some embodiments, identifying real-world users may comprise identifying specific identifiable individuals associated with the entity. In some embodiments, identifying real-world users may comprise identifying hypothetical or potential individuals associated with the entity. Identifying hypothetical or potential individuals may comprise aggregating data about specific identifiable individuals or using other data to predict the characteristics of the hypothetical or potential individuals.

In some embodiments, identifying real-world users may comprise identifying the real-world users' association with the entity. For example, identifying real-world users associated with an entity may comprise analyzing data to identify the entity's customer base, including how many customers the entity has in a given year, for example, and characteristics of the customer base, including how the customer base may be divided and categorized based on various factors. For example, identifying the real-world users of a toy company may comprise identifying the number of customers the toy company had in the past year and categorizing the customers as parents of babies, parents of toddlers, or parents of pre-teen children, among other categories. In another example, identifying the real-world users of a financial institution may comprise identifying all resource accounts (e.g., savings account, credit card account, checking account, etc.) maintained and/or managed by the financial institution. Identifying real-world users of an entity may also comprise identifying the employees or stakeholders of the company and identifying their association with the entity. For example, with respect to the toy company, employees may comprise salespersons at the toy stores, IT professionals who work on the company's commercial websites, managers for each department, marketing professionals, etc. Identifying real-world users and their association with the entity may be important because individuals in each role may have different priorities and may behave in different ways as well.

As shown in block 404, the process flow 400 may include the step of receiving data associated with the real-world users. In some embodiments, the data may comprise at least one of characteristics and behavioral patterns of each of the real-world users or group characteristics of a subset of the real-world users. Characteristics and behavioral patterns of each of the real-world users means, with respect to each identified real-world user, details about the user and data about how they behave. For example, with respect to the toy company, characteristics and behavioral patterns of one customer may include whether the customer is a parent, whether the customer is a parent to a baby, a toddler, or a pre-teen child, how often the customer visits the toy store, how much the customer spends in a visit, the types of toys the customer purchases, and the like. Group characteristics of a subset of the real-world users, on the other hand, may comprise characteristics of each category of real-world users identified in the step above, as described with respect to block 402. For example, with respect to the toy company, one subset of the real-world users of the toy company may comprise the parents of toddlers. Group characteristics of the subset of parents of toddlers may comprise the average number of visits among individuals in the subset, the average amount spent, the most popular toys, and the like. Group characteristics may be received from the entity or may be determined by analyzing data associated with individual real-world users. For example, upon receiving a vast amount of data of all of the toy company's customers and the customers'characteristics and behavioral patterns, the AI model may analyze the data and determine the group characteristics of various subsets of the real-world users and transmit such determined data to the system provided for in this disclosure.

In some embodiments of the disclosure, receiving data associated with the real-world users may comprise at least one of collecting the data in real time from the real-world users; or collecting the data from logs of historical data associated with the real-world users. For example, and in some embodiments, collecting data in real time may comprise monitoring user activity of one or more real-world users on entity systems and analyzing the user activity to determine the data associated with the real-world users. For example, with respect to the toy company, collecting data in real time may comprise monitoring the toy company's commercial sales websites and tracking user accounts, which pages on the website the users visit, which users add which toys to the cart, the purchases made by the users, and the like. In another example, with respect to the financial institution, collecting data in real-time may comprise monitoring financial transactions performed by the user and financial products, financial tools, and/or the like accessed by the user. In some embodiments, collecting data in real time may also comprise requesting and receiving feedback from the real-world users in real time. For example, with respect to the toy company, the company's website may have an option for the users to rate their experience or may have a chatbot function that allows the users to interact with the company's employees. The system may collect data regarding both the users and their questions or comments and the employees and their responses in that scenario. Collecting the data from logs of historical data associated with the real-world users on the other hand may comprise gathering data regarding past purchases or prior surveys, for example. Logs of historical data may be received from the entity, from the entity's systems, or from one or more real-world users. In some embodiments, logs of historical data may comprise data previously collected in real time by the system.

As shown in block 406, the process flow 400 may include the step of generating digital twins. In some embodiments, an AI model may be used to generate the digital twins. In some embodiments, the AI model may comprise an ML model, as described in FIG. 2 herein, and/or a generative AI model, as described in FIG. 3 herein. A digital twin may, in and of itself, be an artificial intelligence (AI) model, comprising an ML mode, as described in FIG. 2 herein and/or a generative AI model, as described in FIG. 3 herein. A digital twin may be capable of receiving and analyzing data, generating data or content, and performing tasks. A digital twin may do any of the foregoing using artificial intelligence.

In some embodiments, each of the digital twins has a real-world user counterpart. In other words, each digital twin may be generated to represent a real-world user. This may be done by using the data associated with a real-world user to generate and train the digital twin to be associated with that real-world user. In some embodiments, and as an example, a digital twin may be generated to be a one-to-one copy of a real-world user in that the digital twin is configured to analyze and generate data and perform tasks the way the real-world user would. In some embodiments, a group of digital twins may be generated to represent a group of users. For example, with respect to customers of an entity, a group of 10 digital twins may be generated to represent a group of 100 customers. In that case, each digital twin may be generated to represent, i.e. analyze and generate data and perform tasks like, a combination of some number of the 100 customers. Alternatively, a group of 100 digital twins may be generated to represent a group of 10 customers. In that case, 10 digital twins may independently represent each customer. In this way, each of the 10 digital twins representing one customer may behave like the customer may have some variations in their outputs. This may provide a better and sometimes more nuances representation of the one customer.

In some embodiments, the digital twin being a one-to-one copy of a real-world user may mean the digital twin is a copy of a specific identifiable individual. In some embodiments, a digital twin being a one-to-one copy of a real world user may mean that the digital twin is generated using more generic characteristics of a type of a real-world user.

In some embodiments of the disclosure, the digital twins can interact with the entity, through the transmission of data between the digital twin and one or more of the entity's systems. In some embodiments, a digital twin can interact with a real-world user or another individual not associated with the entity. A digital twin can interact with a real-world user by generating data and transmitting data to user device associated with the real-world user. The real-world user may respond by transmitting data via the user device back to the digital twin.

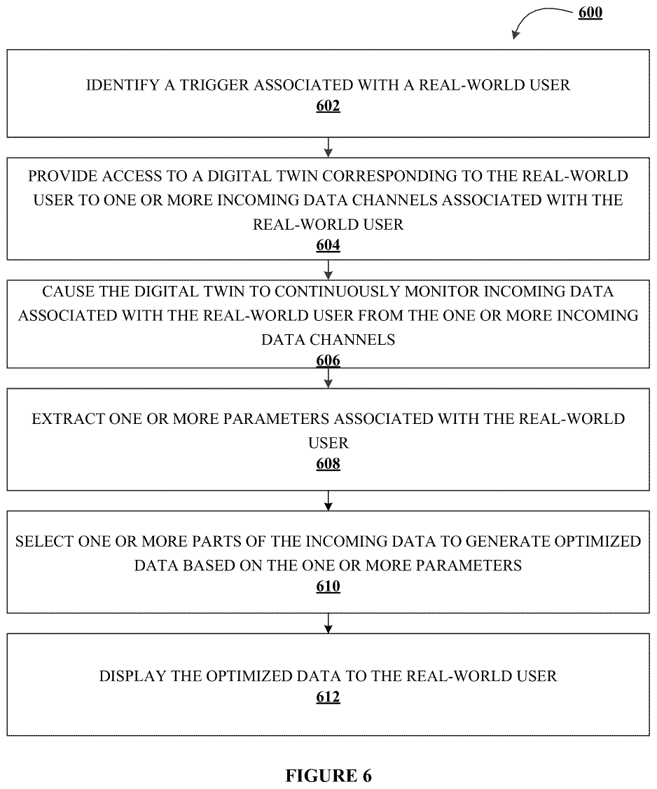

In some embodiments of the disclosure, each digital twin may be configured to perform tasks. Examples of the tasks are described in detail in FIG. 6. In some embodiments, the digital twin may perform tasks autonomously. The digital twin may, based on how the digital twin was trained, may determine a task to be performed and execute the determined task without additional instruction. In some embodiments, the digital twin may perform tasks at the instruction of a real-world user. The real-world user may initiate an interaction with the digital twin to provide the digital twin with instructions on a task to perform or the real-world user may provide instructions during an existing interaction with the digital twin. One real-world user may provide instructions for more than one digital twin. One digital twin may receive instructions from more than one real-world user.

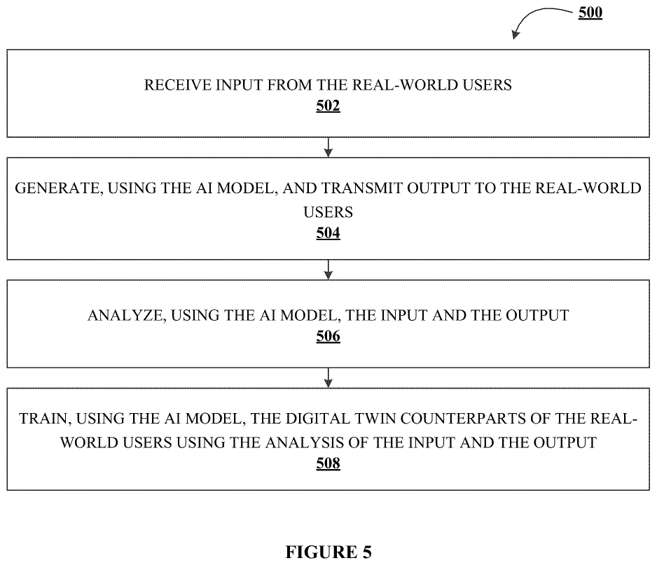

In some embodiments of the disclosure, a real-world user may train the real-world user's digital twin counterpart. In some embodiments, the real-world user may train a digital twin that is a one-to-one copy of the specific real-world use individual. In some embodiments, the real-world user may train a digital twin that more generically represents the real-world user of a group the real-world user is a part of. In some embodiments, one real-world user may train one or more digital twins. In some embodiments, one digital twin may be trained by one or more real-world users. Training a digital twin may comprise receiving input from the real-world user; and generating and transmitting output to the real-world user. In some embodiments, this essentially means the digital twin interacting with the real-world user. The digital twin and the real-world user, in some embodiments, may interact until the end of the real-world user's user session. Training the digital twin may further comprise analyzing the input and output and using the analysis to train the digital twin by feeding data associated with the analysis to the digital twin. An embodiment of training a digital twin is further described with respect to FIG. 5 below.

In some embodiments of the disclosure, the digital twins may be configured to interact with a product prototype to provide feedback regarding the product prototype. A product prototype, in some embodiments, may comprise any product or hypothetical product associated with an entity, or any materials generated by or associated with the entity. Interacting with a product prototype to provide feedback may comprise receiving a request for feedback from a requestor, receiving interaction data from the real-world user, the entity, or a system of the entity; receiving pre-defined metrics from the real-world user, the entity, or the system of the entity, analyzing the interaction data based on the predefined metrics, generating feedback based on the analysis of the interaction data, and transmitting the feedback to the requestor.

An example of how a digital twin may interact with a provide feedback on a product prototype is as follows. In the example, the entity may be a software development company, and the product prototype may be a recently developed software. The lead developer may request feedback from one or more digital twins. The lead developer may also provide pre-defined metrics to the digital twin, where pre-defined metrics are essentially what the lead developer wants the digital twin to provide feedback related to. For example, with respect to the software, the pre-defined metrics may comprise functionality and user-friendliness of the software. The digital twin may then receive interaction data, wherein interaction data may comprise a vast amount of data regarding how the software work. For example, interaction data may comprise information on what happens when you hover over a particular button or what happens when you click a particular button. In some embodiments, the digital twin may transmit data to the software or to the real-world user or the system that is providing the interaction data to the digital twin asking questions. For example, the digital twin may transmit data to the software essentially telling the software to do what it would do if a real-world user was hovering over a button and the software may transmit data back to the digital twin telling the digital twin what happened. Or the digital twin may ask the real-world user what would happen if the real-world user hovers over the button and the real-world user would tell the digital twin, where asking and telling are both conducted as transmissions of data. The digital twin may then analyze all of the interaction data, generate feedback on how functional and user-friendly the software is and transmit the feedback to the requestor.

For another example of interaction data, let's take the example of the toy company where a toy developer requests feedback on a newly developed toy. Interaction data in that case may comprise schematics and blueprints of the toy and detailed information about exactly how the toy works, dimensions, functionality, how different pieces of the toy may connect with each other or move, and the like.

In some embodiments of the disclosure, a real-world user can create a subset of the digital twins based on one or more of the characteristics and behavioral patterns associated with the digital twins or the group characteristics associated with the digital twins. For example, with respect to the toy company, a real-world user associated with the toy company may create a subset of digital twins associated with parents of babies. A requestor of feedback may generate a subset of digital twins to request feedback from. For example, in the example above, the toy developer may generate a subset of digital twins associated with parents of babies who have purchased a toy from the company within the past year and request feedback on whether the newly developed toy would likely be purchased by such parents.

As shown in block 408, the process flow 400 may include the step of generating a network. In some embodiments, an AI model may be used to generate the digital twins. In some embodiments, the AI model may comprise an ML model, as described in FIG. 2 herein, and/or a generative AI model, as described in FIG. 3 herein. In some embodiments, the network comprises a plurality of the digital twins. In some embodiment, the network comprises all the digital twins generated that are associated with the real-world users of an entity.

In some embodiments, the network comprises the digital twins necessary for the network to be an accurate representation of the entity. For example, if an entity has 1 owner, 10 employees, and 100 customers, the network may comprise 1 digital twin associated with the owner, 10 digital twins associated with each of the 10 employees, and 100 digital twins associated with each of the 100 customers. In some embodiments, an accurate representation of the entity may occur if the digital twins in the network are in the same ratio as real-world users associated with the entity. For example, if an entity has 1 owner, 10 employees, and 100 customers, the network may comprise 10 digital twins that represent the 1 owner, 100 digital twins that represent the 10 employees, and 1000 digital twins that represent the 100 customers and still be an accurate representation.

In some embodiments of the disclosure, each digital twin in a network is linked to the other. In some embodiments, this means that each digital twin may transmit data to and receive data from another digital twin in the network. In some embodiments of the disclosure, the digital twins in the network may interact with one another by transmitting data between themselves.

In some embodiments of the disclosure, each of the digital twins, within the network, may have the same role as the real world counterpart of the digital twin. For example, in the example where a network comprises 1 digital twin associated with 1 owner, 10 digital twins associated with each of 10 employees, and 100 digital twins associated with each of 100 customers, those associations determine the digital twins'roles in the network. Within the network, the digital twin associated with the owner behaves as and takes on the role of the owner, the digital twins associated with the employees behave as a take on the role of the employees of the owner and the digital twins associated with the customers behave as and take on the role of customers. In some embodiments, for example, the employee digital twins may take instruction from the owner digital twin, but the owner digital twin may not have to take instruction from the employee digital twins. As another example, if 1 of the 10 employees includes a financial advisor, 1 of the 10 employee digital twins may represent the financial advisor, behaving as and taking on the role of a financial advisor within the network.

In some embodiments of the disclosure, a digital twin may perform tasks at the instruction of another digital twin. One digital twin may instruct another through the transmission of data comprising the instructions.

An example of how digital twins may be used to perform tasks is as follows. Taking the marketing manager example above, the marketing manager of a toy company, in this example, may require feedback on how an advertisement for a new toy plays with the toy's target audience, parents with babies. In this example, the marketing manager is a real-world user associated with the toy company. As provided in the example above, the marketing manager may provide multiple digital twins associated with a customer group, e.g., multiple digital twins associated with parents of babies, with the new advertisement for the toy intended for babies and instruct the digital twins to review the advertisement and provide feedback on the advertisement. Alternatively, the network of digital twins generated for the toy company may comprise digital twins representing the employees of the toy company and the customers of the toy company. Thus, the marketing manager's digital twin counterpart, the marketing manager digital twin, may take on the marketing manager's role within the network. The marketing manager may provide the marketing manager digital twin with the advertisement and instruct the marketing manager digital twin to gather feedback on the effectiveness of the advertisement with the target audience. The marketing manager digital twin may then convene a panel of digital twins associated with parents of babies and instruct the digital twins on the panel to provide feedback on the effectiveness of the advertisement. Furthermore, the marketing manager may instruct the marketing manager digital twin to update the advertisement using the feedback. Upon receiving the feedback from the panel of digital twins, the marketing manager digital twin may analyze the feedback and update the advertisement by modifying elements of the advertisement. In this way, digital twins may take instructions from real-world users or from other digital twins and digital twins can take on the roles of their real-world counterparts. As another example, if another employee of the toy company includes a financial advisor, the network may comprise a financial advisor digital twin as well. The marketing manager may send sales data to the financial advisor digital twin to analyze the data from the financial advisor's perspective.

As another example, where an entity is a financial institution, a manager associated with the financial institution may refer a customer who wants to open an account to an employee digital twin. The customer may interact with the employee digital twin directly and the employee digital twin can open the account for the customer. In this way, digital twins can take on the roles of their real-world user counterparts to perform tasks for other real-world users as well.

FIG. 5 illustrates a process flow 500 for training digital twin counterparts, in accordance with an embodiment of the disclosure. In some embodiments, a system (e.g., similar to one or more of the systems described herein with respect to FIGS. 1A-1C) may perform one or more of the steps of process flow 500. For example, a system (e.g., the system 130 described herein with respect to FIGS. 1A-1C) may perform the steps of process flow 500. Additionally, and in some embodiments, an ML model (like the ML model shown and described above with respect to FIG. 2) and/or a generative AI model (like that shown and described above with respect to FIG. 3) may perform one or more of the steps of process flow 500.

As shown in block 502, the process flow 500 may include the step of receiving input from the real-world users. In some embodiments, input is received directly by the digital twin. In some embodiments, real-world users may provide input via a user interface associated with a user device of the real-world user. Input may comprise text input, audio input, video input, documents, files, and the like. Additionally, input may comprise choosing between multiple options, approving an action, completing a survey, and the like. Real-world users may initiate the process by providing input to the digital twins. Alternatively, real-world users may provide input in response to being prompted for input.

As shown in block 504, the process flow 500 may include the step of generating and transmitting output to the real-world users. In some embodiments, the AI model may be used to generate output. In some embodiments, the AI model may comprise an ML model, as described in FIG. 2 herein, and/or a generative AI model, as described in FIG. 3 herein. In some embodiments, the digital twin generates and transmits output to the real-world users. In some embodiments, the generated output is transmitted to the user device of the real-world user. The output may be displayed to the real-world user via a physical component of the user device, such as a screen. In some embodiments, the digital twin may, via the generated output, prompt the real-world user to provide input. In some embodiments, the digital twin may respond to the real-world user's input via the generated output. In some embodiments, the real-world user may interact with the output via the user interface associated with the user device of the real-world user. For example, the real-world user may approve or reject an output by selecting a green or red button associated with the output. Such interaction may also be the real-world user's input.

In some embodiments, the process of receiving input and generating and transmitting output may occur repeatedly. Essentially, in some embodiments, the digital twin and the real-world user interact with one another. For example, the digital twin and the real-world user may interact with each other through a chat function where each can ask the other questions or answer the other's questions or otherwise provide each other information. In this example, the digital twin and the real-world user may essentially be talking to each through the real-world user's input and the digital twin's output.

In another example, the real-world user may monitor the activities of the real-world user's digital twin counterpart. Each of the digital twin counterpart's actions may be transcribed into a readable form for the real-world user to review in real time. The real-world user may approve each action or reject an action and provide instructions on what the digital twin counterpart should do instead. In some embodiments, the actions of the digital twin counterpart may be provided to the real-world user later and not in real time.

As shown in block 506, the process flow 500 may include the step of analyzing the input and the output. In some embodiments, the AI model may be used to analyze the input and the output. In some embodiments, the AI model may comprise an ML model, as described in FIG. 2 herein, and/or a generative AI model, as described in FIG. 3 herein. In some embodiments of the disclosure, analyzing the input and output comprises determining modifications required for the digital twin to be a more accurate representation of the real-world user.

In some embodiments, analyzing the input and the output may comprise identifying differences associated with the input and the output to determine how the digital twin needs to be modified. For example, if the real-world user consistently rejects a certain type of action taken by the digital twin and proposes a different action instead, analyzing the input and the output may comprise identifying the type of action rejected and comparing the action taken by the digital twin with the proposed alternative actions to determine what actions would be acceptable in that scenario instead.

In some embodiments of the disclosure, analyzing the input and the output may comprise identifying differences between the characteristics and behavioral patterns of the real-world user in the input and the output generated by the digital twins. For example, if the digital twin generates text output that uses abbreviations for certain words, but the real-world user never abbreviates those words, that may be determined to be an implementable change-that the digital twin should also not abbreviate those words when it is behaving as or taking on the role of the real-world user.

As shown in block 508, the process flow 500 may include the step of training the digital twin counterparts of the real-world users using the analysis of the input and the output. In some embodiments, the AI model may be used to analyze the input and the output. In some embodiments, the AI model may comprise an ML model, as described in FIG. 2 herein, and/or a generative AI model, as described in FIG. 3 herein. In some embodiments of the disclosure, training the digital twin comprises modifying the digital twin to change its functionality or behavior. In some embodiments, the digital twin may itself comprise artificial intelligence that is capable of receiving data and modifying its own features according to such data. In such embodiments, the digital twin essentially self-trains, learning from all the data it receives. In some embodiments, the digital twin receives data associated with the analysis from the system. In other embodiments, the digital twin analyzes the input and output itself. The digital twin may then use that data to improve its functionality and modify its features.

Essentially, the digital twin learns from its interactions with the real-world user. The digital twin's learning process may be iterative where it continuously learns from its interactions. In some embodiments, the process of receiving input, generating and transmitting output, analyzing the input and output, and training the digital twin may occur continuously and repeatedly until the end of a user session. In some embodiments, the end of a user session may be any time the real-world user stops interacting with the digital twin. In some embodiments, the end of a user session may be determined by the lapse of a certain period of time. In some embodiments, the digital twin may be trained on each individual interaction with the real-world user, i.e., after every input or output. In some embodiments, the digital twin may be trained after the end of the user session using all the interactions from the user session, i.e., all the inputs and outputs transmitted during the user session.

FIG. 6 illustrates a process flow for generating and selecting optimized data for presentation to an associated user, in accordance with an embodiment of the disclosure. In some embodiments, a system (e.g., similar to one or more of the systems described herein with respect to FIGS. 1A-1C) may perform one or more of the steps of process flow 600. For example, a system (e.g., the system 130 described herein with respect to FIGS. 1A-1C) may perform the steps of process flow 600. Additionally, and in some embodiments, an ML model (like the ML model shown and described above with respect to FIG. 2) and/or a generative AI model (like that shown and described above with respect to FIG. 3) may perform one or more of the steps of process flow 600.

As shown in block 602, the process flow 600 may include the step of identifying a trigger associated with a real-world user. In one embodiment, the trigger may comprise receiving a request from a real-world user to monitor incoming data and generate optimized data from the incoming data. For example, the real-world user may submit a request to monitor one or more email accounts, text messages, and/or any other electronic communications received by the real-world user from incoming data channels and filter out communications that are relevant to the user. In another embodiments, the trigger may comprise the real-world user providing a new user goal to the digital twin corresponding to the user. In some embodiments, the trigger may comprise an entity user associated with an entity, managing, maintaining, and/or controlling data associated with the real-time user providing a request to the digital twin to monitor incoming data and generating optimized data from the incoming data.

As shown in block 604, the process flow 600 may include the step of providing access to a digital twin corresponding to the real-world user to one or more incoming data channels associated with the real-world user. The one or more incoming data channels may comprise any of the channels used by the user to receive data transmissions from other real-world users (that may or may not be associated with the entity). Examples of the one or more incoming data channels may comprise digital instant messengers, text channels, email channels, web channels, and/or the like. In some embodiments, the system may monitor the one or more incoming data channels, extract incoming data from the one or more incoming data channels and provide the extracted incoming data to the digital twin. In some embodiments, the system may provide access associated with the one or more incoming data channels to the digital twin. In some such embodiments, the system may provide access associated with the one or more incoming data channels to the digital twin after receiving approval from the real-world user.

As shown in block 606, the process flow 600 may include the step of causing the digital twin to continuously monitor incoming data associated with the real-world user from the one or more incoming data channels. In some embodiments, the system may cause digital twin to instantaneously categorize and segregate the incoming data from the one or more incoming channels.

As shown in block 608, the process flow 600 may include the step of extracting one or more parameters associated with the real-world user. The one or more parameters may comprise user preferences (e.g., personal communications from specific users (family, coworkers, and/or the like), interests in one or more topics (finance, medicine, technology, and/or the like), etc.), user parameters (e.g., employment position, year of birth, etc. of the real-world user), user requirements (e.g., user goals, etc.), and/or the like associated with the real-world user. In some embodiments, the step described in block 608 may be performed right after identifying the one or more triggers in block 602. In some such embodiments, the instantaneous categorization and segregation of the incoming data may be based on the one or more parameters.

As shown in block 610, the process flow 600 may include the step of selecting one or more parts of the incoming data to generate optimized data based on the one or more parameters. The system may cause the digital twin to select relevant data out of the incoming data based on the one or more parameters to generate the optimized data. For example, the one or more parameters may comprise user preferences comprising interests in ‘X’ technology, the system may filter and select all electronic communications associated with the ‘X’ technology received from all electronic channels to generate optimized data comprising the electronic communications associated with the ‘X’ technology. In some embodiments, the system may summarize the contents of the electronic communications associated with the ‘X’ technology and may generate the optimized data comprising the summary.

As shown in block 612, the process flow 600 may include the step of displaying the optimized data to the real-world user. In some embodiments, the system may use one or more visualization elements to display the optimized data. In some embodiments, the system may display the optimized data on a platform/application associated with an electronic channel that is most frequently accessed by the real-world user. For example, the system may determine that the user accesses a web application frequently and may display the optimized data on the web application. In some embodiments, the system may generate and display optimized data for every incoming data channel associated with the real-world user. For example, if the real-world user receives electronic communications from email channel and web channel, the system may generate a first optimized data associated with the email channel, a second optimized data associated with the web channel, and display the first optimized data on the email channel, and the second optimized data on the web channel.

In some embodiments, the digital twin may perform one or more actions autonomously, at one or more instructions received from the real-world user, where the one or more actions may be associated with the optimized data generated by the digital twin. Examples of one or more actions may comprise responding to an incoming communication on behalf of the real-world user. In some embodiments, the system of the invention may implement a smart contract to control the use of the incoming data associated with the real-world user by the digital twin to allow for secure use and access of the incoming data. For example, the smart contract may place restriction on transmission of the incoming data in outgoing transmissions of the real-world user that are performed by the digital twin.

In some embodiments, where the trigger described in block 602 is associated with an updated user goal of the real-world user, the system may cause the digital twin to generate optimized plans for the real-world user based on the updated user goal. In some embodiments, the system may cause the digital twin to generate real-time simulations of the optimized plans to achieve the updated user goal of the real-world user and may display the real-time simulations to the real-world user. In some embodiments, the digital twin may be implement one or more steps associated with the optimized plan of the real-world user, at an instruction of the real-world user. For example, if the updated goal of the real-world user is to save ‘X’ amount of dollars within ‘Y’ time frame, the system may generate optimized plans for achieving the goal, run real-time simulations of the optimized plans, and may implement steps of an optimized plan that the real-world user has approved, where the steps may comprise removing subscriptions to a product, opening an account, and/or the like.

As will be appreciated by one of ordinary skill in the art, the present disclosure may be embodied as an apparatus (including, for example, a system, a machine, a device, a computer program product, and/or the like), as a method (including, for example, a business process, a computer-implemented process, and/or the like), as a computer program product (including firmware, resident software, micro-code, and the like), or as any combination of the foregoing. Many modifications and other embodiments of the present disclosure set forth herein will come to mind to one skilled in the art to which these embodiments pertain having the benefit of the teachings presented in the foregoing descriptions and the associated drawings. Although the figures only show certain components of the methods and systems described herein, it is understood that various other components may also be part of the disclosures herein. In addition, the method described above may include fewer steps in some cases, while in other cases may include additional steps. Modifications to the steps of the method described above, in some cases, may be performed in any order and in any combination.

Therefore, it is to be understood that the present disclosure is not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. A system for using digital twins to select and generate optimized data for presentation to an associated user, the system comprising:
at least one memory device comprising non-transitory computer-readable medium with computer-readable program code stored thereon;
at least one processing device operatively couples to the at least one memory device and at least one communication device, wherein when executed, the computer-readable code is configured to cause the at least one processing device to:
identify, using an artificial intelligence (AI) model, real-world users associated with an entity;
receive data associated with the real-world users, wherein the data comprises at least one of characteristics and behavioral patterns of each of the real-world users or group characteristics of a subset of the real-world users;
generate, using the AI model, a digital twin for each of the real-world users, based on the data associated with the real-world users;
provide incoming data associated with each of the real-world users to the digital twin corresponding to each of the real-world users;
cause the digital twin to generate optimized data from the incoming data; and
display the optimized data to a real-world user associated with the digital twin.

2. The system of claim 1, wherein the computer-readable code is configured to cause the at least one processing device to implement a smart contract to control use of the incoming data and the optimized data generated from the incoming data by the digital twin.

3. The system of claim 1, wherein the computer-readable code is configured to cause the at least one processing device to provide at least one parameter associated with the real-world user to the digital twin, wherein the at least one parameter is used by the digital twin to generate the optimized data.

4. The system of claim 3, wherein the at least one parameter comprises at least one of user preferences, user goals, and user requirements associated with the real-world user.

5. The system of claim 1, wherein one or more of the real-world users train digital twin counterparts of the real-world users, wherein training the digital twin counterparts comprises:
receiving input from the real-world users;
generating, using the AI model, and transmitting output to the real-world users;
analyzing, using the AI model, the input and the output; and
training, using the AI model, the digital twin counterparts of the real-world users using the analysis of the input and the output.

6. The system of claim 5, wherein training the digital twin counterparts further comprise receiving input, generating and transmitting output, analyzing the input and output, and training the digital twin continuously and repeatedly until an end of a user session with the real-world user.

7. The system of claim 1, wherein the computer-readable code is configured to cause the at least one processing device to cause the digital twin to performs actions autonomously, at an instruction of the real-world user, wherein the actions are associated with the optimized data generated by the digital twin.

8. The system of claim 1, wherein receiving the data associated with the real-world users comprises at least one of:
collecting the data in real time from the real-world users; or
collecting the data from logs of historical data associated with the real-world users.

9. The system of claim 1, wherein the computer-readable code is configured to cause the at least one processing device to generate one or more simulations associated with the real-world user, via the digital twin.

10. A computer implemented method for using digital twins to select and generate optimized data for presentation to an associated user, the computer implemented method comprising:
identifying, using an artificial intelligence (AI) model, real-world users associated with an entity;
receiving data associated with the real-world users, wherein the data comprises at least one of characteristics and behavioral patterns of each of the real-world users or group characteristics of a subset of the real-world users;
generating, using the AI model, a digital twin for each of the real-world users, based on the data associated with the real-world users;
providing incoming data associated with each of the real-world users to the digital twin corresponding to each of the real-world users;
causing the digital twin to generate optimized data from the incoming data; and
displaying the optimized data to a real-world user associated with the digital twin.

11. The computer implemented method of claim 10, wherein the method comprises implementing a smart contract to control use of the incoming data and the optimized data generated from the incoming data by the digital twin.

12. The computer implemented method of claim 10, wherein the method comprises providing at least one parameter associated with the real-world user to the digital twin, wherein the at least one parameter is used by the digital twin to generate the optimized data.

13. The computer implemented method of claim 12, wherein the at least one parameter comprises at least one of user preferences, user goals, and user requirements associated with the real-world user.

14. The computer implemented method of claim 10, wherein the method further comprises causing the digital twin to performs actions autonomously, at an instruction of the real-world user, wherein the actions are associated with the optimized data generated by the digital twin.

15. The computer implemented method of claim 10, wherein the method further comprises generating one or more simulations associated with the real-world user, via the digital twin.

16. A computer program product for using digital twins to select and generate optimized data for presentation to an associated user, wherein the computer program product comprises at least one non-transitory computer-readable medium having computer-readable program code portions embodied therein, the computer-readable program code portions which when executed by a processing device are configured to cause the processing device to:
identify, using an artificial intelligence (AI) model, real-world users associated with an entity;
receive data associated with the real-world users, wherein the data comprises at least one of characteristics and behavioral patterns of each of the real-world users or group characteristics of a subset of the real-world users;
generate, using the AI model, a digital twin for each of the real-world users, based on the data associated with the real-world users;
provide incoming data associated with each of the real-world users to the digital twin corresponding to each of the real-world users;
cause the digital twin to generate optimized data from the incoming data; and
display the optimized data to a real-world user associated with the digital twin.

17. The computer program product of claim 16, wherein the computer-readable program code portions which when executed by a processing device are further configured to cause the processing device to implement a smart contract to control use of the incoming data and the optimized data generated from the incoming data by the digital twin.

18. The computer program product of claim 16, wherein the computer-readable program code portions which when executed by a processing device are further configured to cause the processing device to provide at least one parameter associated with the real-world user to the digital twin, wherein the at least one parameter is used by the digital twin to generate the optimized data.

19. The computer program product of claim 16, wherein the computer-readable program code portions which when executed by a processing device are further configured to cause the processing device to generate one or more simulations associated with the real-world user, via the digital twin.

20. The computer program product of claim 16, wherein the computer-readable program code portions which when executed by a processing device are further configured to cause the processing device to cause the digital twin to performs actions autonomously, at an instruction of the real-world user, wherein the actions are associated with the optimized data generated by the digital twin.
